(19) United States
(12) Patent Application Publication
(10) Pub. No.: US 2026/0190526 A1
(43) Pub. Date: Jul. 2, 2026

(54) IMAGE SENSOR PACKAGE AND CAMERA MODULE INCLUDING THE SAME

(71) Applicant: SAMSUNG ELECTRO-MECHANICS CO., LTD., Suwon-si (KR)

(72) Inventors: Wonseo GU, Suwon-si (KR); Sangjin KIM, Suwon-si (KR)

(73) Assignee: SAMSUNG ELECTRO-MECHANICS CO., LTD., Suwon-si (KR)

(21) Appl. No.: 19/222,870

(22) Filed: May 29, 2025

(30) Foreign Application Priority Data
Dec. 31, 2024 (KR) 10-2024-0202231

(51) Int. Cl. H10F 39/00

(52) U.S. Cl. CPC H10F 39/8063; H10F 39/804; H10F 39/811

(57) ABSTRACT

A camera module is provided. The camera module includes an image sensor; a board electrically connected to the image sensor; a support member, seated on the image sensor, and supporting an infrared filter so that the infrared filter is spaced apart from the image sensor in an optical axis direction; a lens holder seated on the board and supporting a lens barrel; and a reinforced bonding part disposed between a top of the support member and an inner surface of the lens holder, wherein the top portion of the support member faces the inner surface of the lens holder.

### CROSS-REFERENCE TO RELATED APPLICATIONS

This application claims the benefit under 35 USC § 119(a) of Korean Patent Application No. 10-2024-0202231 filed on Dec. 31, 2024, in the Korean Intellectual Property Office, the entire disclosure of which is incorporated herein by reference for all purposes.

### BACKGROUND

### 1. Field

The following description relates to an image sensor package and a camera module including the same.

### 2. Description of Related Art

Recently, a chip on board (COB) method has become the most commonly used method for manufacturing a camera module of a mobile device. This COB method is a method for directly mounting a semiconductor chip on a printed circuit board (PCB), and may be suitable for the miniaturization and mass production of the camera module. Currently, most camera module manufacturers adopt this COB method to produce products.

A COB process may broadly include three main processes: a die attach (D/A) process for attaching an image sensor to the PCB, a wire bonding (W/B) process for connecting the sensor to a PCB pattern using a gold wire, and a housing attach (H/A) process for mounting a housing to which a lens is attached. Through this manufacturing process, the camera module having various pixels has been manufactured and is currently mass-produced.

Following a recent trend in the mobile device market, the camera module is becoming more high-resolution while also becoming smaller. In particular, as the number of pixels increases, a size of the lens may increase, while a height of the entire module needs to remain the same or even decrease. To satisfy this market demand, it is beneficial to develop a new camera module structure that may minimize a package space by improving an existing general housing structure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a camera module includes an image sensor; a board electrically connected to the image sensor; a support member, seated on the image sensor, and supporting an infrared filter so that the infrared filter is spaced apart from the image sensor in an optical axis direction; a lens holder seated on the board and supporting a lens barrel; and a reinforced bonding part disposed between a top portion of the support member and an inner surface of the lens holder, wherein the top portion of the support member faces the inner surface of the lens holder.

The reinforced bonding part may include epoxy resin.

The support member may be fixed to an upper surface of the image sensor using an adhesive material.

The support member may include a step portion that is disposed at the top portion of the support member, and the infrared filter is mounted on the step portion.

In a general aspect, a camera module includes an image sensor; a board electrically connected to the image sensor; a support member, seated on the image sensor, and supporting an infrared filter so that the infrared filter is spaced apart from the image sensor in an optical axis direction; and a lens holder seated on the board and supporting a lens barrel, wherein a bottom surface of the support member that faces an upper surface of the image sensor includes irregularities.

The irregularities may be disposed with recesses and protrusions that are alternately arranged in a direction along an edge of the image sensor.

The support member may include a step portion that is disposed at a top portion of the support member, and the infrared filter is mounted on the step portion.

A region of a plane perpendicular to the board may have an area that is greater than an area of the infrared filter, and the region of the plane may be surrounded by an outer edge of the support member.

The image sensor may include an active region including a center area of the image sensor, a wiring region that surrounds the active region and is disposed along an edge of the image sensor, and an intermediate region that is disposed between the active region and the wiring region, the bottom surface of the support member may be disposed in the intermediate region, and an adhesive material is interposed between the bottom surface of the support member and the upper surface of the image sensor.

The adhesive material may include epoxy resin.

A top surface of the support member may face an inner surface of the lens holder, and a reinforced bonding part may be disposed between the top surface of the support member and the inner surface of the lens holder.

The reinforced bonding part may include epoxy resin.

The camera module may include a bonding wire that electrically connects the image sensor to the board; and a wiring mold part that covers and protects the bonding wire.

In a general aspect, an image sensor package includes an image sensor; a board electrically connected to the image sensor; and a support member, seated on the image sensor, and supporting an infrared filter so that the infrared filter is spaced apart from the image sensor in an optical axis direction, wherein a bottom surface of the support member that faces an upper surface of the image sensor includes irregularities.

The irregularities may be disposed with recesses and protrusions that are alternately arranged in a direction along an edge of the image sensor.

The support member may include a step portion that is disposed at a top portion of the support member, and the infrared filter is mounted on the step portion.

A region of a plane perpendicular to the board may have an area that is greater than an area of the infrared filter, and the region of the plane may be surrounded by an outer edge of the support member.

The image sensor may include an active region including a center area of the image sensor, a wiring region that surrounds the active region and may be disposed along an edge of the image sensor, and an intermediate region that is disposed between the active region and the wiring region,

The adhesive material may include epoxy resin.

The image sensor package may include a bonding wire that electrically connects the image sensor to the board; and a wiring mold part that covers and protects the bonding wire.

Other features and aspects will be apparent from the following detailed description, the drawings, and the claims.

### BRIEF DESCRIPTION OF DRAWINGS

FIG. 1 illustrates a cross-sectional view of an example camera module, in accordance with one or more embodiments.

FIG. 2 illustrates a cross-sectional view taken along line A-A′ of FIG. 1.

FIG. 3 illustrates a bottom view of a support member of the example camera module shown in FIG. 1.

FIG. 4 illustrates a plan view of an example image sensor package of the example camera module shown in FIG. 1.

FIG. 5 and FIG. 6 are plan views of the example image sensor package according to modified examples.

FIG. 7 illustrates a cross-sectional view of an example camera module, in accordance with one or more embodiments.

FIG. 8 illustrates a cross-sectional view of an example camera module, in accordance with one or more embodiments.

FIG. 9 illustrates a cross-sectional view of an example camera module, in accordance with one or more embodiments.

FIG. 10 illustrates a partial cross-sectional view of a portion of an example camera module, in accordance with one or more embodiments.

FIG. 11 illustrates a partial cross-sectional view of a portion of an example camera module, in accordance with one or more embodiments.

FIG. 12 illustrates a cross-sectional view of an example camera module, in accordance with one or more embodiments.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but is used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Throughout the specification, when a component or element is described as “on,” “connected to,” “coupled to,” or “joined to” another component, element, or layer, it may be directly (e.g., in contact with the other component, element, or layer) “on,” “connected to,” “coupled to,” or “joined to” the other component element, or layer, or there may reasonably be one or more other components elements, or layers intervening therebetween. When a component or element is described as “directly on”, “directly connected to,” “directly coupled to,” or “directly joined to” another component element, or layer, there can be no other components, elements, or layers intervening therebetween. Likewise, expressions, for example, “between” and “immediately between” and “adjacent to” and “immediately adjacent to” may also be construed as described in the foregoing.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

In this specification, “plane” indicates a view of an object as viewed from above, and “cross-sectional” indicates a view of a cross-section cut vertically through the object as viewed from a side.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment (e.g., as to what an example or embodiment may include or implement) means that at least one example or embodiment exists where such a feature is included or implemented, while all examples are not limited thereto. The use of the terms “example” or “embodiment” herein have a same meaning (e.g., the phrasing “in one example” has a same meaning as “in one embodiment”, and “one or more examples” has a same meaning as “in one or more embodiments”).

One or more examples may provide an image sensor package which may ensure stable optical performance while effectively reducing an overall module height by overcoming a limitation of an existing housing structure despite the use of a large lens desired for a high-resolution camera module, and a camera module including the same.

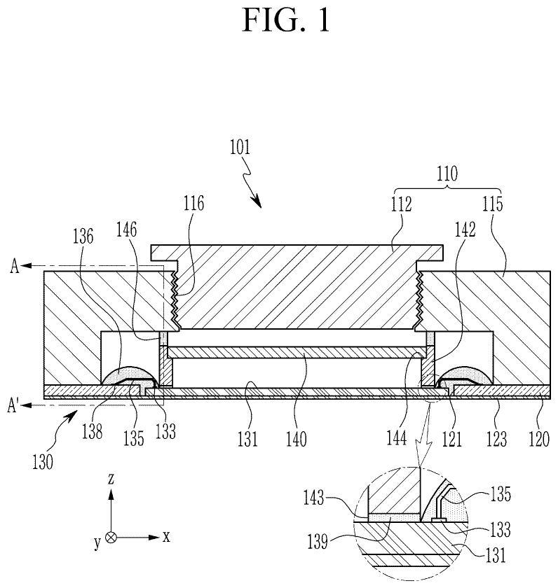

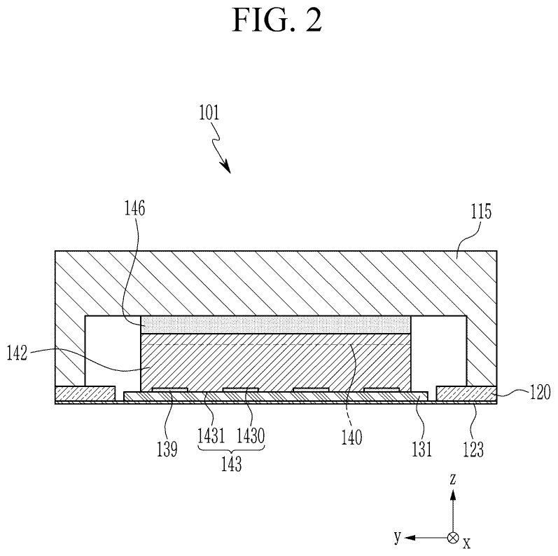

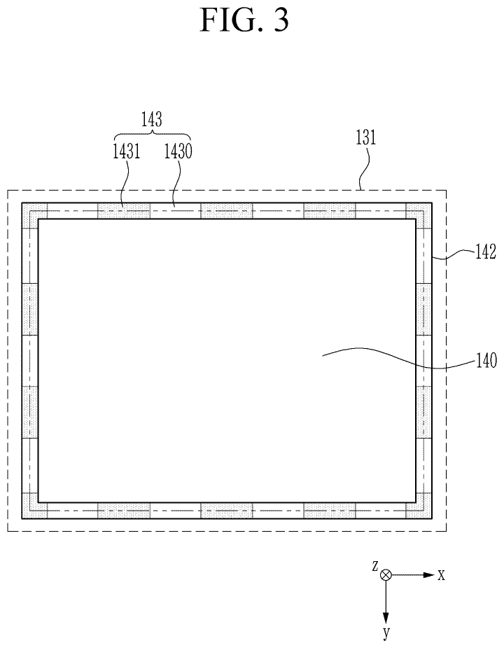

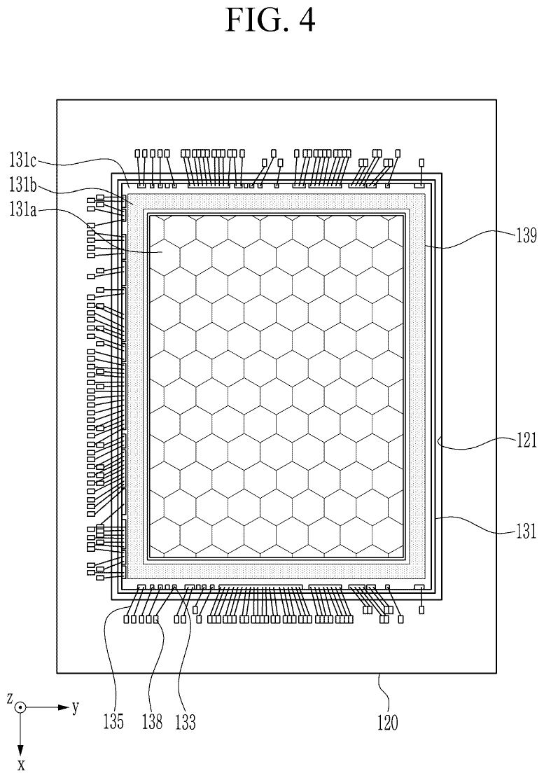

FIG. 1 is a cross-sectional view illustrating an example camera module, in accordance with one or more embodiments, and FIG. 2 is a cross-sectional view taken along line A-A′ of FIG. 1 FIG. 3 is a bottom view showing a support member of the example camera module shown in FIG. 1. FIG. 4 is a plan view showing an image sensor package of the example camera module shown in FIG. 1.

Referring to FIG. 1, a camera module 101, in accordance with one or more embodiments, may include a lens barrel 112, a lens holder 115 supporting the lens barrel 112, an image sensor 131, a board 120 connected to the image sensor 131, an infrared filter 140, and a support member 142 supporting the infrared filter 140.

The lens barrel 112 may accommodate at least one lens that captures an image of a subject. When a plurality of lenses are disposed or implemented in the optical system, the plurality of lenses may be mounted inside the lens barrel 112 along an optical axis direction. The lens barrel 112 may have a hollow cylindrical shape, and may be coupled to the lens holder 115 to thus form a lens module 110. The lens module 110 may be accommodated in a housing (not shown), and an actuator (not shown) that moves the lens module 110 in an optical axis direction and/or in a direction perpendicular to the optical axis direction may also be disposed in the housing.

An image sensor package 130 may be disposed below the lens module 110 where the lens barrel 112 and the lens holder 115 are coupled to each other. The image sensor package 130 is a part that converts light incident through the lens module 110 into an electrical signal.

The image sensor package 130 may include the image sensor 131, the board 120, the infrared filter 140, and the support member 142. The image sensor 131 may be electrically connected to the board 120, and the infrared filter 140 may be seated on, and supported by, the support member 142. The image sensor 131 may convert light incident through the lens module 110 into the electrical signal. In a non-limited example, the image sensor 131 may be a charge coupled device (CCD) or a complementary metal-oxide semiconductor (CMOS), as only examples. The electrical signal converted by the image sensor 131 may be output as an image through a display device of an electronic device. The infrared filter 140 may block light in an infrared region from light incident through the lens module 110.

The image sensor 131 may be electrically connected to the board 120 via a bonding wire 135. The board 120 may be a printed circuit board, and may include a circuit to transmit the electrical signal converted from the image sensor 131 to the outside. The image sensor 131 and the board 120 may have bonding pads 133 and 138, respectively. The bonding wire 135 may be bonded to the bonding pads 133 and 138 to electrically connect the image sensor 131 to the board 120. The bonding wire 135 may be covered and protected by a wiring mold part 136 while being bonded to the image sensor 131 and the bonding pads 133 and 138 of the board 120.

The lens holder 115 may be seated on the board 120 at an outer edge of the image sensor 131. The bottom of the lens holder 115 may be disposed on the board 120 and fixed to the outside of the wiring mold part 136. Therefore, the wiring mold part 136 may be disposed between the support member 142 and the bottom of the lens holder 115.

In this embodiment, the board 120 may have a board opening 121 as an accommodation space to accommodate the image sensor 131. The board opening 121 may be formed as a hole that passes through the board 120. The image sensor 131 may be inserted into the board opening 121. In an example, an upper surface of the image sensor 131 may be disposed to be lower than an upper surface of the board 120. The image sensor 131 may be inserted into the board opening 121, thus reducing an overall height of the camera module 101 by a height of the image sensor 131 compared to an example where the image sensor 131 is mounted on the upper surface of the board 120.

The through hole-shaped board opening 121 may be disposed in the board 120, and a reinforcing plate 123 may thus be disposed to reinforce the rigidity of the board 120. The reinforcing plate 123 may be made of a metal and coupled to the bottom of the board 120. The reinforcing plate 123 may be coupled to the bottom of the board 120 to cover the board opening 121. Therefore, even though the through hole-shaped board opening 121 is disposed in the board 120, its rigidity may be reinforced by the reinforcing plate 123, thus preventing the board 120 and the image sensor 131 from being damaged during a manufacturing process and usage. The reinforcing plate 123 may have a thickness that is less than a thickness of the board 120.

In this embodiment, the support member 142 may be seated on the image sensor 131. The infrared filter 140 may be spaced apart from the image sensor 131 in the optical axis direction (z-axis direction in the drawing) while being supported by the support member 142. A region of a plane, surrounded by an outer edge of the support member 142, may have an area larger than that of the infrared filter 140. Therefore, the infrared filter 140 may be disposed within a region defined by the outer edge of the support member 142. The support member 142 may include a step portion 144 disposed at its top, and the infrared filter 140 may be mounted on the step portion 144. The infrared filter 140 may be mounted on the step portion 144 of the support member 142, and each of the image sensor package 130 and the camera module may thus have a height that is reduced by a height of the infrared filter 140.

In this embodiment, an upper part of the lens holder 115 may have a holder opening 116 in, or through which, the lens barrel 112 is mounted. The holder opening 116 may have a diameter that is less than a diameter of a region surrounded by the bottom of the lens holder 115. Therefore, the upper part of the lens holder 115 may extend from its bottom toward the center of the image sensor 131, and the top of the support member 142 may face an inner surface of the lens holder 115. A reinforced bonding part 146 may be disposed between the top of the support member 142 and the inner surface of the lens holder 115 that face each other in the optical axis direction. The reinforced bonding part 146 may fix the top of the support member 142 to the inner surface of the lens holder 115, and may firmly maintain a position of the support member 142. The reinforced bonding part 146 may be formed by applying epoxy resin to the top of the support member 142.

The step portion 144 of the support member 142 may include an upper surface and a lower surface having different heights. The reinforced bonding part 146 may be disposed on the upper surface of the step portion 144, and the infrared filter 140 may be seated on the lower surface of the step portion 144.

Referring to FIG. 2, the bottom of the support member 142 that faces an upper surface of the image sensor 131 may include irregularities 143. The irregularities 143 on the bottom of the support member 142 may be configured with recesses 1430 and protrusions 1431 alternately arranged along an edge of the support member 142. Additionally, the protrusion 1431 may also be disposed at each corner of the support member 142. In an example, the protrusion 1431 may have a height of approximately 30 micrometers relative to a bottom surface of the recess 1430.

An adhesive material 139 (FIG. 1) may be interposed between the bottom of the support member 142 and the upper surface of the image sensor 131. Therefore, the adhesive material 139 may be interposed between the recess 1430 or the protrusion 1431 and the upper surface of the image sensor 131. The adhesive material 139 interposed between the recess 1430 and the image sensor 131 may be cured while filling a space in the recess 1430. The adhesive material 139 interposed between the protrusion 1431 and the image sensor 131 may be cured while being compressed by the protrusion 1431. In this way, the irregularities 143 may be disposed on the bottom of the support member 142, thereby preventing the infrared filter 140 or the support member 142 from being tilted or twisted when the support member 142 is attached and fixed to the upper surface of the image sensor 131 and the infrared filter 140 is then seated on the support member 142.

FIG. 3 illustrates the support member 142 on which the infrared filter 140 is seated, viewed upward from below. Referring to FIG. 3, the support member 142 may have an approximately rectangular frame structure when viewed on the plane perpendicular to the optical axis direction. The irregularities 143 disposed on the bottom of the support member 142 may be configured by alternating the recess 1430 and the protrusion 1431 in a direction extending along an edge of the image sensor 131, and the protrusion 1431 may also be disposed at each corner of the support member 142.

Referring to FIG. 4, the image sensor 131 may include an active region 131a, an intermediate region 131b, and a wiring region 131c. The active region 131a is a region including the center of the image sensor 131, the wiring region 131c is a region surrounding the active region 131a and disposed along the edge of the image sensor 131, and the intermediate region 131b is a region disposed between the active region 131a and the wiring region 131c. The bottom of the support member 142 may be disposed in the intermediate region 131b.

The adhesive material 139 interposed between the bottom of the support member 142 and the upper surface of the image sensor 131 may be disposed along the intermediate region 131b of the image sensor 131 and may include the epoxy resin. The support member 142 may be attached and fixed to the upper surface of the image sensor 131 using the adhesive material 139.

In this embodiment, the adhesive material 139 may be disposed in a continuous line shape along the intermediate region 131b of the image sensor 131. Therefore, the adhesive material 139 may be applied to both the recess 1430 and protrusion 1431 of the irregularities 143 disposed on the bottom of the support member 142. The adhesive material 139 applied to the recess 1430 may be cured while filling the space in the recess 1430, and the adhesive material 139 applied to the protrusion 1431 may be cured while being compressed by the protrusion 1431.

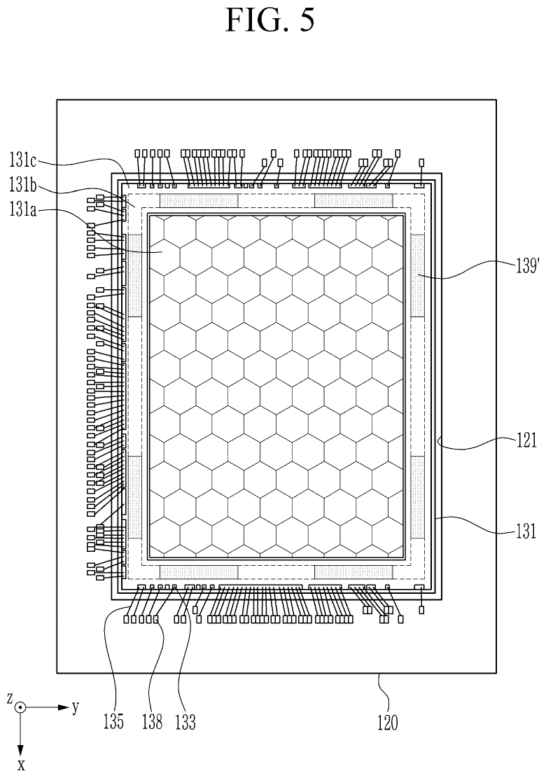

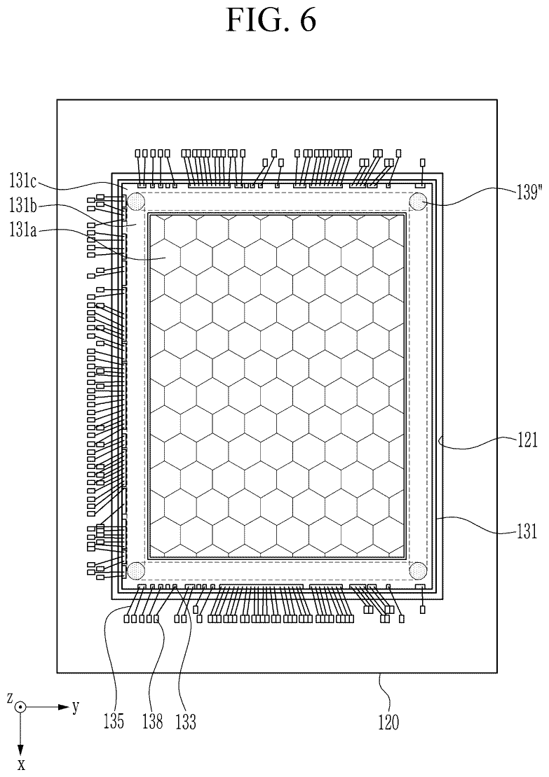

FIGS. 5 and 6 are plan views illustrating the image sensor package according to modified examples.

Referring to FIG. 5, in the image sensor package 130 according to a modified embodiment, an adhesive material 139′ for attaching the support member 142 to the image sensor 131 may be disposed in the intermediate region 131b of the image sensor 131. The adhesive material 139′ may be intermittently applied along the intermediate region 131b and positioned accordingly. For example, the intermediate region 131b may have a rectangular frame structure including long sides and short sides, and the adhesive material 139′ may be applied to two separate adhesive regions on each of the long sides and the short sides. Each adhesive region may have the shape of a bar extending along the long side or the short side, and the adhesive material 139′ may include the epoxy resin.

Referring to FIG. 6, in the image sensor package 130 according to another modified example, an adhesive material 139″ may be independently applied and positioned on each of four corners of the intermediate region 131b of the image sensor 131. For example, the intermediate region 131b may have the rectangular frame structure including the long side and the short side, and each adhesive material 139″ may have a circular plane and be disposed on each corner of the rectangular frame.

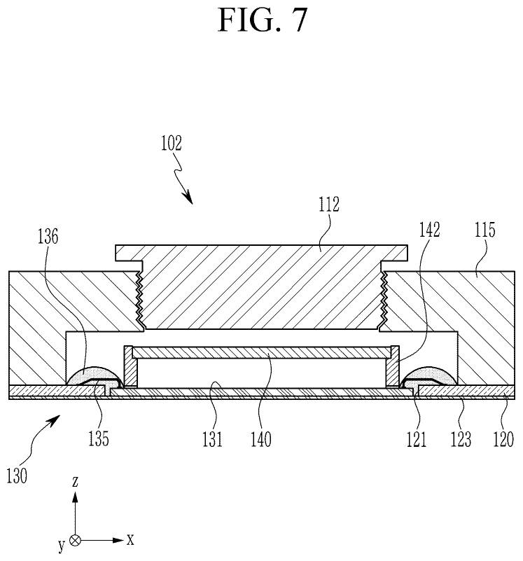

FIG. 7 is a cross-sectional view illustrating an example camera module, in accordance with one or more embodiments.

Referring to FIG. 7, an example camera module 102, in accordance with one or more embodiments, may include the lens barrel 112, the lens holder 115, the infrared filter 140, the support member 142, the image sensor 131, and the board 120, similar to the camera module 101 shown in FIG. 1.

However, the camera module 102 according to this embodiment may not include the reinforced bonding part disposed between the top of the support member 142 and the inner surface of the lens holder 115. Therefore, the bottom of the support member 142 may be attached and fixed to the upper surface of the image sensor 131, whereas the top of the support member 142 may not be fixed to the inner surface of the lens holder 115.

The remaining configurations other than those described above are the same as those described with reference to FIG. 1, and their redundant descriptions are thus omitted.

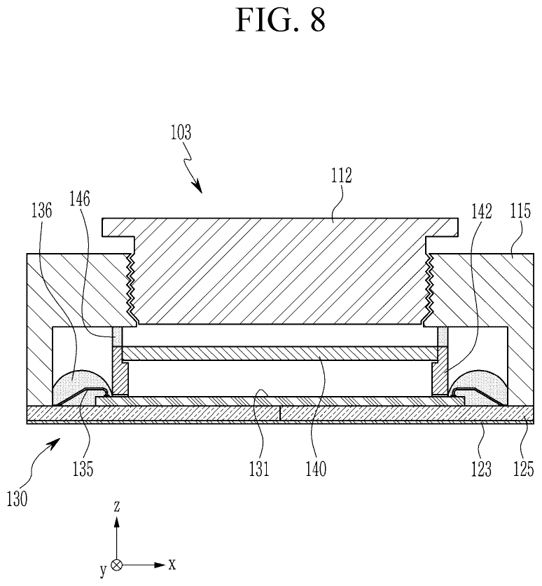

FIG. 8 illustrates a cross-sectional view of an example camera module, in accordance with one or more embodiments.

Referring to FIG. 8, a camera module 103 according to this embodiment may include the lens barrel 112, the lens holder 115, the infrared filter 140, the support member 142, the image sensor 131, and a board 125.

The image sensor package 130 may include the image sensor 131, the board 125, the infrared filter 140, and the support member 142. The image sensor 131 may be electrically connected to the board 125, and the infrared filter 140 may be seated on, and supported by, the support member 142.

In this embodiment, the board 125 may not have the board opening. Therefore, the image sensor 131 may be disposed on, and fixed to, the board 125.

The remaining configurations other than those described above are the same as those described with reference to FIG. 1, and their redundant descriptions are thus omitted.

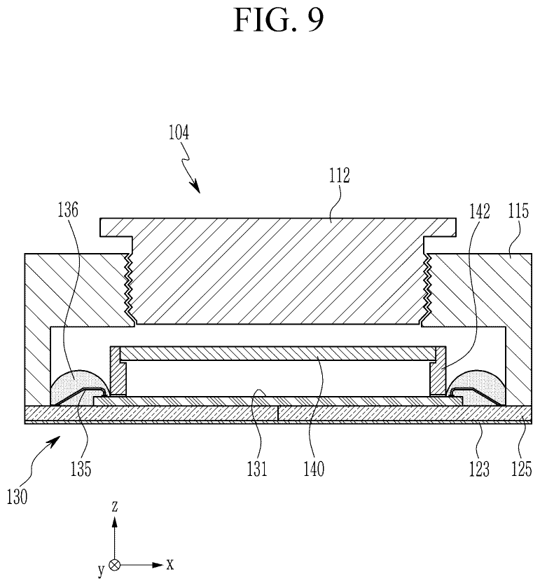

FIG. 9 illustrates a cross-sectional view of an example camera module, in accordance with one or more embodiments.

Referring to FIG. 9, a camera module 104 according to this embodiment may include the lens barrel 112, the lens holder 115, the infrared filter 140, the support member 142, the image sensor 131, and the board 125, similar to the camera module 103 shown in FIG. 8.

However, the camera module 104 according to this embodiment includes the board 125 electrically connected to the image sensor 131, and the board 125 may not have the board opening. Therefore, the image sensor 131 may be disposed on, and fixed to, the board 125.

Additionally, the camera module 104 according to this embodiment may not include the reinforced bonding part disposed between the top of the support member 142 and the inner surface of the lens holder 115. Therefore, the bottom of the support member 142 may be attached and fixed to the upper surface of the image sensor 131, whereas the top of the support member 142 may not be fixed to the inner surface of the lens holder 115.

The remaining configurations other than those described above are the same as those described with reference to FIG. 1, and their redundant descriptions are thus omitted.

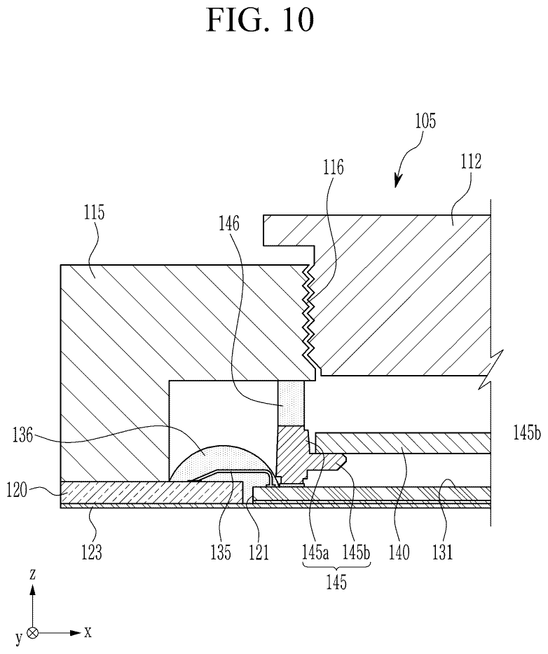

FIG. 10 is a partial cross-sectional view illustrating a portion of the camera module, in accordance with one or more embodiments.

Referring to FIG. 10, a camera module 105 according to this embodiment may include the lens barrel 112, the lens holder 115, the infrared filter 140, a support member 145, the image sensor 131, and the board 120, similar to the camera module 101 shown in FIG. 1.

However, in the camera module 105 according to this embodiment, the support member 145 may include a support 145a and a pedestal 145b. The support 145a may be seated on the image sensor 131, and the pedestal 145b may protrude from a side surface of the support 145a toward the center of the image sensor 131 in a direction perpendicular to the optical axis direction (z-axis direction in the drawing). The pedestal 145b may be spaced apart from the image sensor 131 in the optical axis direction, and the infrared filter 140 may be seated on, and supported by, the pedestal 145b.

The support 145a of the support member 145 may selectively include the components of the support member described with reference to FIGS. 2 to 6.

The support 145a may have an approximately rectangular frame structure when viewed from the plane perpendicular to the optical axis direction. A region of the plane, surrounded by an outer edge of the support 145a, may have an area that is larger than an area of the infrared filter 140. Therefore, the infrared filter 140 may be disposed within a region defined by the outer edge of the support member 145a.

In this embodiment, the upper part of the lens holder 115 may have the holder opening 116 in which the lens barrel 112 is mounted. The holder opening 116 may have a diameter that is less than a diameter of a region surrounded by the bottom of the lens holder 115. Therefore, the upper part of the lens holder 115 may be extended from its bottom toward the center of the image sensor 131, and the top of the support 145a may face the inner surface of the lens holder 115. The reinforced bonding part 146 may be disposed between the top of the support member 145a and the inner surface of the lens holder 115 that face each other. The reinforced bonding part 146 may fix the top of the support member 145a to the inner surface of the lens holder 115, and thus may firmly maintain a position of the support member 145.

The bottom of the support 145a facing the upper surface of the image sensor 131 may include the irregularities. The irregularities disposed on the bottom of the support 145a may be configured by alternating the recess and the protrusion in the direction extending along the edge of the image sensor 131.

The bottom of the support 145a may be disposed in the intermediate region 131b of the image sensor 131. The adhesive material 139 (FIG. 1) may be interposed between the bottom of the support member 145a and the upper surface of the image sensor 131. The adhesive material 139 may be disposed along the intermediate region 131b of the image sensor 131 and may include the epoxy resin. The adhesive material 139 may be applied either continuously or intermittently along the intermediate region 131b of the image sensor 131, or may be disposed independently on the corner of the image sensor 131. The support 145a may be attached and fixed to the upper surface of the image sensor 131 using the adhesive material 139.

The remaining configurations other than those described above are the same as those described with reference to FIG. 1, and their redundant descriptions are thus omitted.

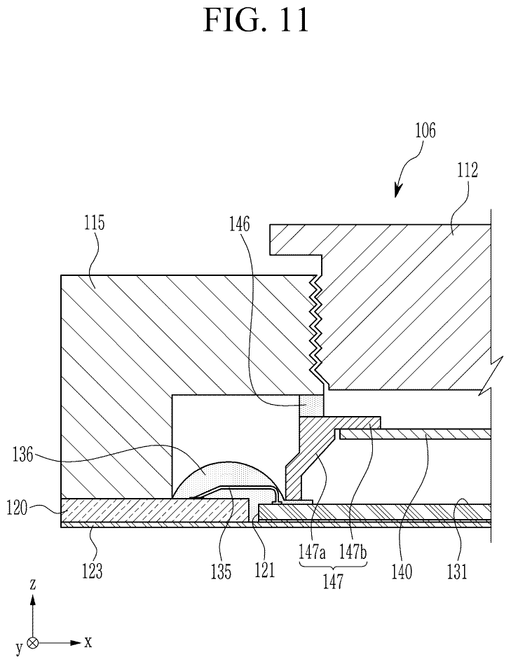

FIG. 11 illustrates a partial cross-sectional view of a portion of the camera module, in accordance with one or more embodiments.

Referring to FIG. 11, a camera module 106 according to this embodiment may include the lens barrel 112, the lens holder 115, the infrared filter 140, a support member 147, the image sensor 131, and the board 120, similar to the camera module 101 shown in FIG. 1.

However, in the camera module 106 according to this embodiment, the support member 147 may include a support 147a and a holding part 147b. The support 147a may be seated on the image sensor 131, and the holding part 147b may protrude from an upper part of the support 147a toward the center of the image sensor 131 in the direction perpendicular to the optical axis direction. The holding part 147b may be spaced apart from the image sensor 131 in the optical axis direction, and the infrared filter 140 may be attached to, and supported by, the bottom of the holding part 147b.

The remaining configurations other than those described above are the same as those described with reference to FIG. 1, and their redundant descriptions are thus omitted.

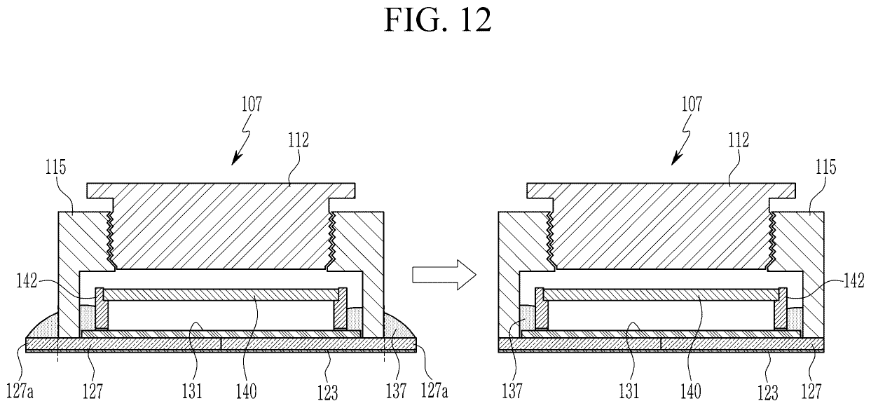

FIG. 12 illustrates a cross-sectional view of an example camera module, in accordance with one or more embodiments.

Referring to FIG. 12, a camera module 107 according to this embodiment may include the lens barrel 112, the lens holder 115, the infrared filter 140, the support member 142, the image sensor 131, and a board 127, similar to the camera module 101 shown in FIG. 1. The board 127 may not have the board opening. Therefore, the image sensor 131 may be disposed on, and fixed to, the board 127.

In the camera module 107 according to this embodiment, the image sensor 131 may be connected to the board 127 without using the bonding wire. Therefore, the bonding wire electrically connecting the image sensor 131 to the board 127 and the wiring mold part that covers and protects the bonding wire may be omitted. An image sensor chip may be directly attached to the printed circuit board by using a method of connecting the image sensor 131 to the board 127 without using the wire bonding, e.g., wafer-level packaging (WLP) technology, or the image sensor may be attached to the printed circuit board by interposing an anisotropic conductive film (ACF) therebetween.

A space for the bonding wire may not be necessary if the image sensor 131 is connected to the board 127 without using the wire bonding. Therefore, the bottom of the lens holder 115 may be attached to and fixed onto the board 127, and then a dummy part 127a of the board 127, which is disposed outside the bottom of the lens holder 115, may be cut and removed. Here, the bottom of the lens holder 115 may be disposed on the board 127 and immediately adjacent to the outer edge of the image sensor 131. The support member 142, the edge of the image sensor 131, and the bottom of the lens holder 115, which are fixed onto the image sensor 131, may be coupled and fixed to one another by applying a mold material 137 thereto.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A camera module, comprising:
an image sensor;
a board electrically connected to the image sensor;
a support member, seated on the image sensor, and supporting an infrared filter so that the infrared filter is spaced apart from the image sensor in an optical axis direction;
a lens holder seated on the board and supporting a lens barrel; and
a reinforced bonding part disposed between a top portion of the support member and an inner surface of the lens holder,
wherein the top portion of the support member faces the inner surface of the lens holder.

2. The camera module of claim 1, wherein
the reinforced bonding part comprises epoxy resin.

3. The camera module of claim 1, wherein
the support member is fixed to an upper surface of the image sensor using an adhesive material.

4. The camera module of claim 1, wherein
the support member comprises a step portion that is disposed at the top portion of the support member, and the infrared filter is mounted on the step portion.

5. A camera module, comprising:
an image sensor;
a board electrically connected to the image sensor;
a support member, seated on the image sensor, and supporting an infrared filter so that the infrared filter is spaced apart from the image sensor in an optical axis direction; and
a lens holder seated on the board and supporting a lens barrel,
wherein a bottom surface of the support member that faces an upper surface of the image sensor includes irregularities.

6. The camera module of claim 5, wherein
the irregularities are disposed with recesses and protrusions that are alternately arranged in a direction along an edge of the image sensor.

7. The camera module of claim 5, wherein
the support member comprises a step portion that is disposed at a top portion of the support member, and the infrared filter is mounted on the step portion.

8. The camera module of claim 5, wherein
a region of a plane perpendicular to the board has an area that is greater than an area of the infrared filter, and
the region of the plane is surrounded by an outer edge of the support member.

9. The camera module of claim 5, wherein
the image sensor comprises an active region including a center area of the image sensor, a wiring region that surrounds the active region and is disposed along an edge of the image sensor, and an intermediate region that is disposed between the active region and the wiring region,
the bottom surface of the support member is disposed in the intermediate region, and an adhesive material is interposed between the bottom surface of the support member and the upper surface of the image sensor.

10. The camera module of claim 9, wherein
the adhesive material comprises epoxy resin.

11. The camera module of claim 5, wherein
a top surface of the support member faces an inner surface of the lens holder, and
a reinforced bonding part is disposed between the top surface of the support member and the inner surface of the lens holder.

12. The camera module of claim 11, wherein
the reinforced bonding part comprises epoxy resin.

13. The camera module of claim 5, further comprising:
a bonding wire that electrically connects the image sensor to the board; and
a wiring mold part that covers and protects the bonding wire.

14. An image sensor package, comprising:
an image sensor;
a board electrically connected to the image sensor; and
a support member, seated on the image sensor, and supporting an infrared filter so that the infrared filter is spaced apart from the image sensor in an optical axis direction,
wherein a bottom surface of the support member that faces an upper surface of the image sensor includes irregularities.

15. The image sensor package of claim 14, wherein
the irregularities are disposed with recesses and protrusions that are alternately arranged in a direction along an edge of the image sensor.

16. The image sensor package of claim 14, wherein
the support member comprises a step portion that is disposed at a top portion of the support member, and the infrared filter is mounted on the step portion.

17. The image sensor package of claim 14, wherein
a region of a plane perpendicular to the board has an area that is greater than an area of the infrared filter, and
the region of the plane is surrounded by an outer edge of the support member.

18. The image sensor package of claim 14, wherein
the image sensor comprises an active region including a center area of the image sensor, a wiring region that surrounds the active region and is disposed along an edge of the image sensor, and an intermediate region that is disposed between the active region and the wiring region,
the bottom surface of the support member is disposed in the intermediate region, and an adhesive material is interposed between the bottom surface of the support member and the upper surface of the image sensor.

19. The image sensor package of claim 18, wherein
the adhesive material comprises epoxy resin.

20. The image sensor package of claim 14, further comprising:
a bonding wire that electrically connects the image sensor to the board; and
a wiring mold part that covers and protects the bonding wire.
